(19) United States
(12) Patent Application Publication
(10) Pub. No.: US 2009/0278557 A1
(43) Pub. Date: Nov. 12, 2009

(54) Power source monitoring device, lens barrel, camera, and power source monitoring method

(75) Inventor: Fumiya Taguchi, Tokyo (JP)

Correspondence Address: OLIFF & BERRIDGE, PLC, P.O. BOX 320850, ALEXANDRIA, VA, 22320-4850, US

(73) Assignee: NIKON CORPORATION, Tokyo (JP)

(21) Appl. No.: 12/219,676

(22) Filed: Jul. 25, 2008

(30) Foreign Application Priority Data
Jul. 27, 2007 (JP) 2007-195707

(51) Int. Cl. G01R 27/00; G01R 19/00

(52) U.S. Cl. 324/713; 324/140 R

(57) ABSTRACT

There are provided a first voltage applied part connected to a first voltage supply part and applied with a first voltage by the first voltage supply part on the basis of a first portion, a second voltage applied part connected to a second voltage supply part and applied with a second voltage by the second voltage supply part on the basis of a second portion, and a voltage monitoring part connected to the second portion and the second voltage applied part, operating when the second voltage is applied, and detecting the first voltage on the basis of the first portion.

### BACKGROUND OF THE INVENTION

1. Field of the Invention

The present invention relates to a power source monitoring device that monitors a voltage of a load.

2. Description of the Related Art

As a device that monitors a voltage of a load provided in a lens barrel, for example, one disclosed in Japanese Patent Application Publication No. 2001-33868 is known.

However, there has been a problem that, when the reference potential of a power source of a load for which the voltage is monitored differs from the reference potential of the power source of the voltage monitoring circuit of the load, the voltage cannot be monitored accurately.

### SUMMARY OF THE INVENTION

The present invention provides a power source monitoring device capable of solving such a problem and accurately monitoring a voltage of a target to be monitored.

In order to achieve the above-mentioned object, a power source monitoring device according to the present invention comprises a first voltage applied part connected to a first voltage supply part and applied with a first voltage by the first voltage supply part on the basis of a first portion, a second voltage applied part connected to a second voltage supply part and applied with a second voltage by the second voltage supply part on the basis of a second portion, and a power source monitoring part connected to the second portion and the second voltage applied part, operating when the second voltage is applied, and detecting the first voltage on the basis of the first portion.

There may be provided a resistor connected to the first portion and the first voltage applied part and applied with the first voltage, and the power source monitoring part may be one which detects the first voltage on the basis of the first portion by detecting the value of a voltage applied to the resistor.

The power source monitoring part may be one which detects the value of a current that flows through the resistor and calculates the value of a voltage applied to the resistor based on the current value and the resistance value of the resistor.

The resistor may include a first resistor and a second resistor connected in series and the power source monitoring part may be one which detects a potential difference between a portion between the first resistor and the second resistor and a portion of the second resistor on the side not connected to the first resistor and calculates the value of a voltage applied to the resistor based on the potential difference and the resistance values of the first resistor and the second resistor.

The resistor may include a first resistor, a second resistor, and a third resistor connected in series and the power source monitoring part may be one which detects a potential difference between a portion between the first resistor and the second resistor and a portion between the second resistor and the third resistor and calculates the value of a voltage applied to the resistor based on the potential difference and the resistance values of the first to third resistors.

The second voltage applied part may be a control circuit.

The first voltage applied part may be a motor.

A power source monitoring device according to the present invention comprises a first voltage applied part connected to a first voltage supply part and applied with a first voltage by the first voltage supply part on the basis of a first portion, a second voltage applied part connected to a second voltage supply part and applied with a second voltage by the second voltage supply part on the basis of a second portion, a resistor connected to the first portion and the first voltage applied part and applied with the first voltage, and a power source monitoring part connected to the second portion and the second voltage applied part, operating when the second voltage is applied, and detecting the value of a voltage applied to the resistor.

The power source monitoring part may be one which detects the value of a current that flows through the resistor and calculates the value of a voltage applied to the resistor based on the current value and the resistance value of the resistor.

The resistor may include a first resistor and a second resistor connected in series and the power source monitoring part may be one which detects a potential difference between a portion between the first resistor and the second resistor and a portion of the second resistor on the side not connected to the first resistor and calculates the value of a voltage applied to the resistor based on the potential difference and the resistance values of the first resistor and the second resistor.

The resistor may include a first resistor, a second resistor, and a third resistor connected in series and the power source monitoring part may be one which detects a potential difference between a portion between the first resistor and the second resistor and a portion between the second resistor and the third resistor and calculates the value of a voltage applied to the resistor based on the potential difference and the resistance values of the first to third resistors.

The second voltage applied part may be a control circuit.

The first voltage applied part may be a motor.

A lens barrel according to the present invention is one which has any of the above-mentioned power source monitoring devices.

A camera according to the present invention is one which has any of the above-mentioned power source monitoring devices.

A camera according to the present invention comprises a camera body having a first voltage supply part that applies a first voltage to a first voltage applied part on the basis of a first portion and a second voltage supply part that applies a second voltage to a second voltage applied part on the basis of a second portion, and a lens barrel having a resistor connected to the first portion and the first voltage applied part and applied with the first voltage and a power source monitoring part connected to the second portion and the second voltage applied part, operating when the second voltage is applied, and detecting the value of a voltage applied to the resistor.

A voltage monitoring method according to the present invention is one which comprises the steps of providing a first voltage applied part applied with a first voltage by a first voltage supply part on the basis of a first portion, providing a second voltage applied part applied with a second voltage by a second voltage supply part on the basis of a second portion, and providing a voltage monitoring part connected to the second portion and the second voltage applied part, operating when the second voltage is applied, and detecting the first voltage on the basis of the first portion.

The method may be one which further comprises the step of providing a resistor connected to the first portion and the first voltage applied part and applied with the first voltage and in which the power source monitoring part detects the first voltage on the basis of the first portion by detecting the value of a voltage applied to the resistor.

The method may be one in which the power source monitoring part detects the value of a current that flows through the resistor and calculates the value of a voltage applied to the resistor based on the current value and the resistance value of the resistor.

The method may be one in which the resistor includes a first resistor and a second resistor connected in series and the power source monitoring part detects a potential difference between a portion between the first resistor and the second resistor and a portion of the second resistor on the side not connected to the first resistor and calculates the value of a voltage applied to the resistor based on the potential difference and the resistance values of the first resistor and the second resistor.

The method may be one in which the resistor includes a first resistor, a second resistor, and a third resistor connected in series and the power source monitoring part detects a potential difference between a portion between the first resistor and the second resistor and a portion between the second resistor and the third resistor and calculates the value of a voltage applied to the resistor based on the potential difference and the resistance values of the first to third resistors.

The second voltage applied part may be a control circuit.

The first voltage applied part may be a motor.

A power source monitoring method according to the present invention is one which comprises the steps of providing a first voltage applied part applied with a first voltage by a first voltage supply part on the basis of a first portion, providing a second voltage applied part applied with a second voltage by a second voltage supply part on the basis of a second portion, providing a resistor connected to the first portion and the first voltage applied part and applied with the first voltage, and providing a power source monitoring part connected to the second portion and the second voltage applied part, operating when the second voltage is applied, and detecting the value of a voltage applied to the resistor.

The method may be one in which the power source monitoring part detects the value of a current that flows through the resistor and calculates the value of a voltage applied to the resistor based on the current value and the resistance value of the resistor.

The method may be one in which the resistor includes a first resistor and a second resistor connected in series and the power source monitoring part detects a potential difference between a portion between the first resistor and the second resistor and a portion of the second resistor on the side not connected to the first resistor and calculates the value of a voltage applied to the resistor based on the potential difference and the resistance values of the first resistor and the second resistor.

The method may be one in which the resistor includes a first resistor, a second resistor, and a third resistor connected in series and the power source monitoring part detects a potential difference between a portion between the first resistor and the second resistor and a portion between the second resistor and the third resistor and calculates the value of a voltage applied to the resistor based on the potential difference and the resistance values of the first to third resistors.

The second voltage applied part may be a control circuit.

The first voltage applied part may be a motor.

### BRIEF DESCRIPTION OF THE DRAWINGS

FIG. 1 is a block diagram showing an electrical configuration of a camera system including an interchangeable lens and a camera body according to an embodiment of the present invention.

FIG. 2 is a block diagram showing an electrical configuration of a camera system including an interchangeable lens and a camera body according to an embodiment of the present invention.

FIG. 3 is a block diagram showing a power source monitoring device according to an embodiment of the present invention.

### DESCRIPTION OF THE PREFERRED EMBODIMENTS

Embodiments of the present invention will be described below based on the drawings.

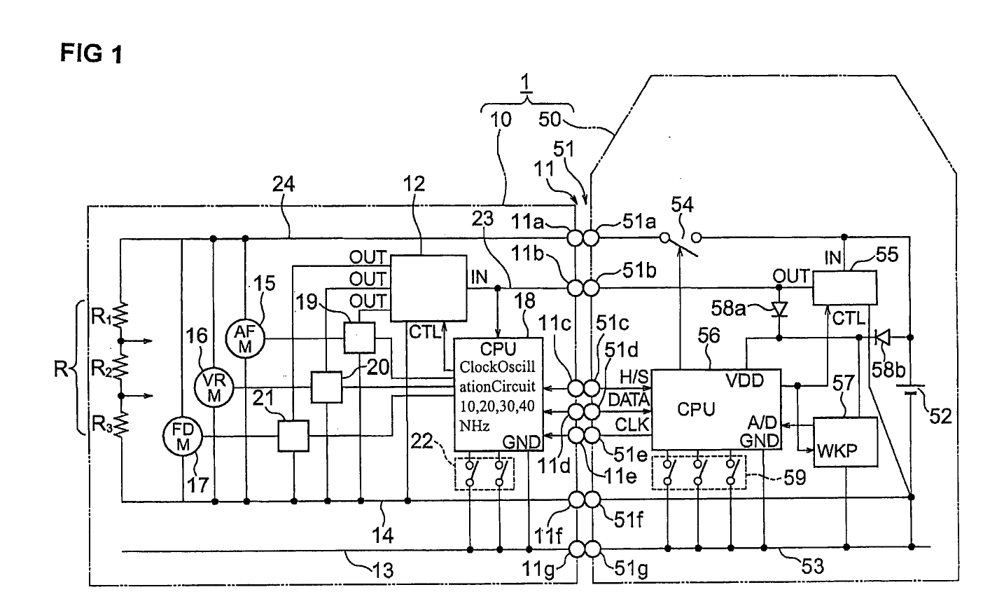

FIG. 1 is a block diagram showing an electrical configuration of essential parts of a camera system including an interchangeable lens and a camera body according to an embodiment of the present invention, omitting part of the configuration of a power source monitoring device.

A camera system 1 shown in FIG. 1 has an interchangeable lens 10 and a camera body 50 and an electrical connection between the interchangeable lens 10 and the camera body 50 is established by connecting attachment contacts 11a to 11g of an attachment part 11 and attachment contacts 51a to 51g of an attachment part 51 provided thereto, respectively.

The camera body 50 is provided with a cell 52, such as a primary cell, secondary cell, or solar cell, and its negative electrode terminal is grounded to a case 53 of the camera body 50 and connected to a case 13 of the interchangeable lens 10 via the attachment contacts 51g, 11g. The negative electrode terminal of the cell 52 is connected to a circuit ground 14 of the interchangeable lens 10 via the attachment contacts 51f, 11f.

On the other hand, the positive electrode terminal of the cell 52 is connected to a feed switch 54 controlled by a CPU 56 and connected to the positive electrode terminals of an autofocus motor 15, a shake correction motor 16, an aperture drive motor 17, and a resistor R including three registers R1, R2, R3 connected in series via the attachment contacts 51a, 11a.

The negative electrode terminals of the autofocus motor 15, the shake correction motor 16, the aperture drive motor 17 and the resistor R are connected to the circuit ground 14.

The positive electrode terminal of the cell 52 is connected to a power supply circuit 55 controlled by the CPU 56 provided in the camera body 50. The output from the power supply circuit 55 is connected to a CPU 18 of the interchangeable lens 10 and a feed circuit 12 via the attachment contacts 51b, 11b.

The CPU 56 and a gyroscope (angular velocity detection part) 57 provided in the camera body 50 are applied with a higher voltage of those of two diodes 58a, 58b connected to the positive electrode terminal of the cell 52 and the output terminal of the power supply circuit 55. Consequently, the CPU 56 of the camera body 50 will activate when the cell 52 is attached.

The ground terminal of the CPU 56 and the ground terminal of the gyroscope 57 are grounded to the case 53 of the camera body 50 similar to the negative electrode terminal of the call 52.

The gyroscope 57 will also operate in a sleep mode when the cell 52 is attached and further when a shutter button, not shown schematically, provided to the camera body 50 is half-pressed by a person who takes a picture, a wakeup signal WKP is input from the CPU 56 and the sleep mode is switched to the normal operation mode and an angular velocity is detected and it is sent out to the CPU 56. The angular velocity detected by the gyroscope 57 is processed in the CPU 56 and the CPU 18 and used for the shake correction in a shake correction circuit 20.

To the CPU 56 of the camera body 50, a signal is input from an external switch group 59 provided in the camera body 50. The external switch group 59 includes various switches, such as a shutter button, a mode setting switch, a command dial, and a film rewinding switch.

On the other hand, to the interchangeable lens 10, the CPU 18 is provided and a signal is input from an external switch 22 provided to the interchangeable lens 10. The external switch 22 includes a switching switch etc. between the automatic mode and the manual mode of autofocus, shake correction, and aperture drive.

The ground terminal of the CPU 18 is grounded to the case 13 of the interchangeable lens 10 and connected to the case 53 of the camera body 50 via the attachment contacts 11g, 51g.

A clock oscillation circuit is incorporated in the CPU 18 so that the clock frequency can be switched among 10 MHz, 20 MHz, 30 MHz, and 40 MHz in accordance with the amount of information to be processed.

The CPU 18 of the interchangeable lens 10 and the CPU 56 of the camera body 50 exchange information via the attachment contacts 11c to 11e, 51c to 51g. In the present embodiment, information is transmitted/received in order to determine whether or not the interchangeable lens 10 is attached, or a standby signal is output from the interchangeable lens 10 for a signal from the camera body 50 (hereinafter, this line is referred to also as handshake line). In addition, various kinds of information possessed by the camera body 50 and various kinds of information possessed by the interchangeable lens 10 are transmitted/received to/from each other via the attachment contacts 11d, 51d. A clock signal is transmitted from the CPU 56 of the camera body 50 to the CPU 18 of the interchangeable lens 10 via the attachment contacts 11e, 51e in order to establish clock synchronization.

To the interchangeable lens 10 in the present embodiment, the feed circuit 12 is provided. The feed circuit 12 is controlled by the CPU 18 and switches between feeding and not feeding power supplied from the power supply circuit 55 of the camera body 50 to an autofocus control circuit 19, the shake correction control circuit 20, and the aperture drive control circuit 21, respectively, based on an instruction signal from the CPU 18.

The autofocus control circuit 19 operates on the power from the feed circuit 12 and at the same time, sends out an operation instruction signal to the autofocus motor 15 based on the instruction from the CPU 18.

The shake correction circuit 20 operates on the power from the feed circuit 12 and at the same time, sends out an operation instruction signal to the shake correction motor 16 based on the instruction from the CPU 18.

The aperture drive control circuit 21 operates on the power from the feed circuit 12 and at the same time, sends out an operation instruction signal to the aperture drive motor 17 based on the instruction from the CPU 18.

The autofocus motor 15, the shake correction motor 16, and the aperture drive motor 17 turn on their respective inner switches when the operation instruction signal is input from the autofocus control circuit 19, the shake control circuit 20, and the aperture drive control circuit 21, respectively, and never operate unless the operation instruction signal is input, thus saving power.

Next, a power source monitoring device in the present embodiment will be described.

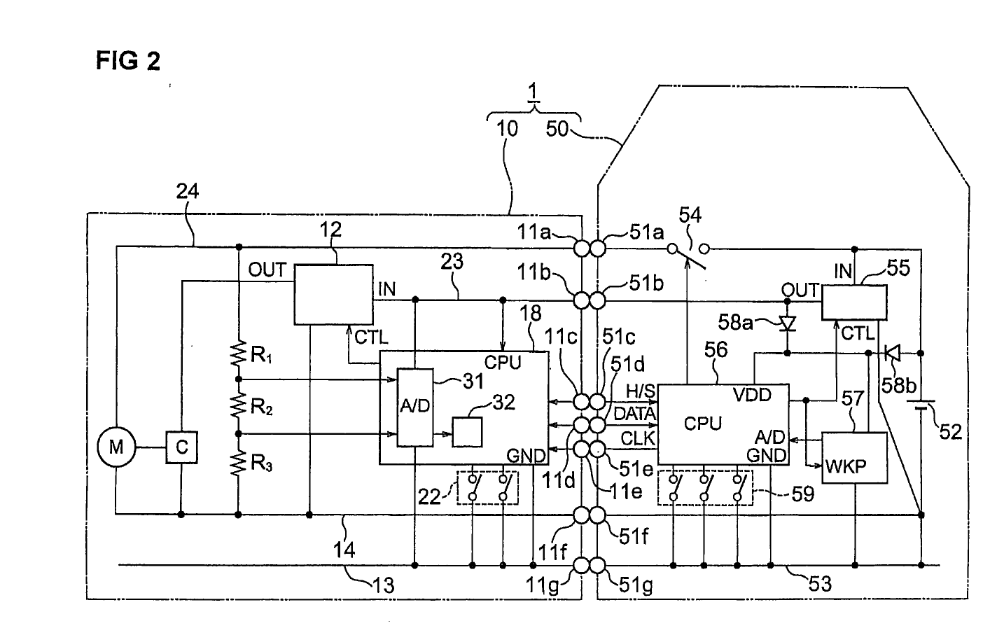

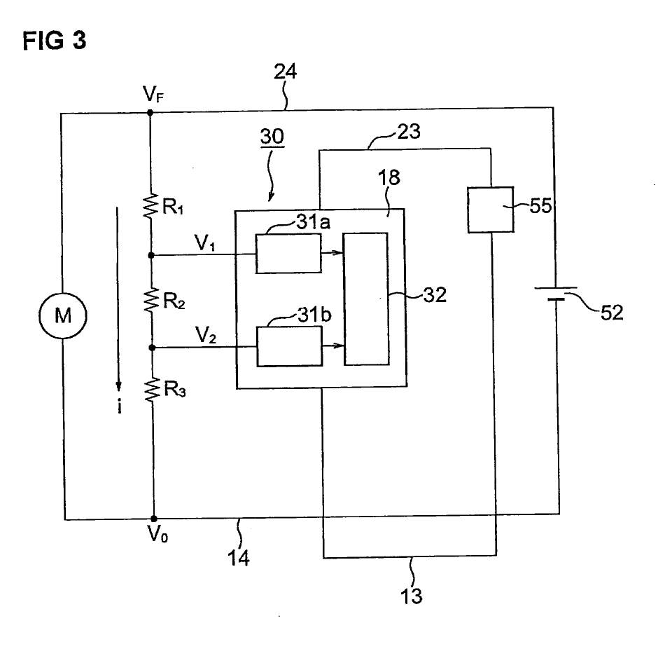

FIG. 2 is a block diagram showing the power source monitoring device according to the present embodiment and only shows a motor M and a control circuit C of the interchangeable lens 10 shown in FIG. 1, simplifying the description of the autofocus motor 15, the shake correction motor 16, the aperture drive motor 17, the autofocus control circuit 19, the shake correction control circuit 20, and the aperture drive control circuit 21. FIG. 3 is a block diagram that extracts only the configuration of the power source monitoring device in the present embodiment.

A power source monitoring device 30 in the present embodiment includes the resistor R consisting of the three resistors R1 to R3 connected in series and the CPU 18 described above. The CPU 18 has an A/D converter 31 and an operation part 32 therein. Then, the A/D converter 31 includes a first voltmeter 31a and a second voltmeter 31b. The first voltmeter 31a detects the value of a voltage at a portion between the resistor R1 and the resistor R2 and the second voltmeter 31b detects the value of a voltage at a portion between the resistor R2 and the resistor R3. The operation part 32 calculates the value of a voltage V_{F} applied to the motor M from the values of the voltages V1 and V2 detected by the first voltmeter 31a and the second voltmeter 31b and the values of the resistors R1 to R3.

The positive electrode terminal of the circuit in which the three resistors R1 to R3 are connected in series is connected to a circuit 24 from the positive electrode terminal of the cell 52 via the attachment contacts 51a, 11a and the negative electrode terminal is connected to the circuit ground 14. That is, the electrode terminals are connected to the same positive electrode terminal and negative electrode terminal as those of the autofocus motor 15, the shake correction motor 16, and the aperture drive motor 17.

In contrast to this, the positive electrode terminal of the A/D converter 31 having the first voltmeter 31a and the second voltmeter 31b is connected from the power supply circuit 55 controlled by the CPU 56 to a circuit 23 via the attachment contacts 51b, 11b, and the negative electrode terminal is connected to the case 13, which is the ground point.

Since the autofocus motor 15, the shake correction motor 16, and the aperture drive motor 17 are connected to the circuit ground 14, the fluctuation in the voltage value is comparatively large at the circuit ground 14. Consequently, if the CPU 18 is connected to the circuit ground 14, there is a possibility that the CPU 18 malfunctions due to the influence of the voltage fluctuation at the circuit ground 14. Then, in the present embodiment, the CPU 18 is grounded by being connected to the case 13. Similarly, also in the camera body 50, the CPU 56 is grounded by being connected to the case 53.

The operation part 32 in the CPU 18 calculates the value of the voltage V_{F} applied to the motor M using the following expression from the values of the voltages V1, V2 detected by the first voltmeter 31a and the second voltmeter 31b and the values of the resistors R1 to R3.

(Expression 1)

V_{F}=(V1−V2)·(R1+R2+R3)/R2 (1)

The grounds of the above expression are as follows. That is, the voltage value V_{F} of the circuit 24 against the circuit ground 14 is expressed as follows, where i denotes a current that flows through the circuit in which the three resistors R1 and R3 are provide, based on Ohm's law,

(Expression 2)

V_{F}=i·(R1+R2+R3) (2)

On the other hand, the current that flows through the resistor R2 is i and the potential difference between both ends of the resistor R2 is V1−V2. Consequently, at the resistor R2, based on Ohm's law, (Expression 3)

i=(V1−V2)/R2 (3)

holds.

By substituting the above expression (3) for expression (2) to delete i, the above-mentioned expression (1) is obtained.

That is, according to the power source monitoring device 30 in the present embodiment, even if the reference potential 13 of the voltage applied to the A/D converter 31 and the CPU 18 differs from the reference potential 14 of the motor M to be monitored due to causes, such as wiring resistance, the voltage value V_{F} applied to the motor M is calculated based on the voltage values V1, V2 in the middle of the three resistors R1, R2, and R3 and the current value i that flows through the resistor R, and therefore, it is possible to accurately obtain the voltage value V_{F}, which is the potential difference for a potential V₀.

Although the resistors R1 and R3 are not necessary in order to obtain the potential difference between both ends of the resistor R2, the resistors R1, R3 are provided in the present embodiment because of the following reasons.

The voltage supplied from the cell 52 is higher than that supplied from the power supply circuit 55 used to drive the CPU 18. In most cases, a tolerance of the voltage value that can be input to the A/D converter 31 of the CPU 18 is less than or equal to the voltage value used for the drive. Consequently, the resistor R1 is provided so that the voltage input to the A/D converter 31 is lower than that supplied from the cell 52, and thereby, it is possible to prevent the tolerance from being exceeded.

Because of the fluctuation in the voltage of the circuit ground 14, there may be the case where the voltage of the circuit ground 14 is lower than that of the case 13 to which the CPU 18 is grounded. In this case, if viewed from the CPU 18, the voltage value of the circuit ground 14 is a negative value. In most cases, the voltage value that can be input to the A/D converter 31 of the CPU 18 is not less than 0 V. Consequently, by providing the resistor R3, it is possible to prevent a negative voltage from being input to the A/D converter 31 even if the voltage of the circuit ground 14 fluctuates.

As described above, in the present embodiment, by providing the resistors R1, R3, it is possible to prevent a voltage outside the tolerance from being input to the A/D converter 31 of the CPU 18 and to protect the CPU 18.

The outline of the operation of the camera system 1 in the present embodiment will be described.

When the cell 52 is attached to the camera body 50, the CPU 56 can activate, as described above, and also the gyroscope 57 can operate in the sleep mode. In this state, when the shutter button, which is one of the external switches 59 of the camera body 50, is half-pressed, the CPU 56 controls to turn on the power supply circuit 55, and thereby, the power is supplied to the CPU 18 from the power supply circuit 55 via the attachment contacts 11b, 51b, and the CPU 18 enters a state in which it can operate. At the same time, the wakeup signal WKP is sent out from the CPU 56 to the gyroscope 57 and the gyroscope 57 switches from the sleep mode to the normal operation state.

Among the external switches 22 of the interchangeable lens 10, if, for example, the autofocus function, the shake correction function, and the aperture drive function are set to the automatic mode, communication of information is established between the CPU 56 and the CPU 18. Then, the CPU 56 switches the feed switch 54 into the ON state and at the same time, the CPU 18 sends out a control signal to the feed circuit 12 and supplies power to the autofocus control circuit 19, the shake correction control circuit 20, and the aperture drive control circuit 21, respectively, from the power supply circuit 55.

When the feed switch 54 turns on, the voltage from the cell 52 is applied to the autofocus motor 15, the shake correction motor 16, and the aperture drive motor 17 and they enter a state in which they can operate. In addition, the power from the power supply circuit 55 is also supplied to the autofocus control circuit 19, the shake correction control circuit 20, and the aperture drive control circuit 21, respectively, and therefore, they enter a state in which they can operate.

Then, for the autofocus function, based on the actual focused state detected in the state where the shutter button is half-pressed, the optimum focus is calculated by the CPU 56 or CPU 18 in accordance with a predetermined autofocus system, and the calculation result is sent out to the autofocus motor 15 via the autofocus control circuit 19 and a focus lens system, not shown schematically, is mechanically driven.

For the shake correction function, using the angular velocity detected by the gyroscope 55, the amount of shake correction is calculated by the CPU 56 or the CPU 18 in accordance with a predetermined shake correction system, and the calculation results are sent out to the shake correction motor 16 via the shake correction control circuit 20, and a shake correction lens, not shown, is mechanically driven.

For the aperture drive function, the optimum aperture amount is calculated by the CPU 56 or the CPU 18 based on the amount of light detected by a light amount sensor, not shown schematically, in accordance with a predetermined aperture system, and the calculation results are sent out to the aperture drive motor 17 via the aperture drive control circuit 21, and an aperture mechanism, not shown schematically, is mechanically driven.

The voltage value V_{F} applied to the autofocus motor 15, the shake correction motor 16, or the aperture drive motor 17 is detected by the above-mentioned power source monitoring device 30. That is, the voltage value V1 between the resistor R1 and the resistor R2 is detected by the first voltmeter 31a and is subjected to A/D conversion and the voltage value V2 between the resistor R2 and the resistor R3 is detected by the second voltmeter 31b and is subjected to A/D conversion. Then, by substituting the two detected voltage values V1, V2 and the already known resistance values of the resistors R1, R2, and R3 for the above-mentioned expression (1), the voltage value V_{F} is obtained.

In the embodiments described above, the configuration is such that the voltage value V_{F} applied to the motor M connected to the cell 52 is monitored using the three resistors R1 to R3 connected to the circuit ground 14 and the circuit 24, however, the number of resistors R is not limited to this, and more resistors R can be used. It is also possible to configure so that the voltage value V_{F} applied to the motor M connected to the cell 52 is monitored using other elements connected to the circuit ground 14 and the circuit 24, besides the use of the resistors R.

What is claimed is:

1. A power source monitoring device, comprising:
a first voltage applied part connected to a first voltage supply part and applied with a first voltage by the first voltage supply part on the basis of a first portion;
a second voltage applied part connected to a second voltage supply part and applied with a second voltage by the second voltage supply part on the basis of a second portion; and
a power source monitoring part connected to the second portion and the second voltage applied part, operating when the second voltage is applied, and detecting the first voltage on the basis of the first portion.

2. The power source monitoring device according to claim 1, further comprising
a resistor connected to the first portion and the first voltage applied part and applied with the first voltage, wherein
the power source monitoring part detects the first voltage on the basis of the first portion by detecting a value of a voltage applied to the resistor.

3. The power source monitoring device according to claim 2, wherein:
the power source monitoring part detects a value of a current that flows through the resistor and calculates a value of a voltage applied to the resistor based on the current value and a resistance value of the resistor.

4. The power source monitoring device according to claim 2, wherein:
the resistor includes a first resistor and a second resistor connected in series; and
the power source monitoring part detects a potential difference between a portion between the first resistor and the second resistor and a portion of the second resistor on a side not connected to the first resistor and calculates a value of a voltage applied to the resistor based on the potential difference and resistance values of the first resistor and the second resistor.

5. The power source monitoring device according to claim 2, wherein:
the resistor includes a first resistor, a second resistor, and a third resistor connected in series; and
the power source monitoring part detects a potential difference between a portion between the first resistor and the second resistor and a portion between the second resistor and the third resistor and calculates a value of a voltage applied to the resistor based on the potential difference and resistance values of the first to third resistors.

6. The power source monitoring device according to claim 1, wherein:
the second voltage applied part is a control circuit.

7. The power source monitoring device according to claim 1, wherein:
the first voltage applied part is a motor.

8. A lens barrel having a power source monitoring device according to claim 1.

9. A camera having a power source monitoring device according to claim 1.

10. A power source monitoring device, comprising:
a first voltage applied part connected to a first voltage supply part and applied with a first voltage by the first voltage supply part on the basis of a first portion;
a second voltage applied part connected to a second voltage supply part and applied with a second voltage by the second voltage supply part on the basis of a second portion;
a resistor connected to the first portion and the first voltage applied part and applied with the first voltage; and
a power source monitoring part connected to the second portion and the second voltage applied part, operating when the second voltage is applied, and detecting a value of a voltage applied to the resistor.

11. The power source monitoring device according to claim 10, wherein:
the power source monitoring part detects a value of a current that flows through the resistor and calculates a value of a voltage applied to the resistor based on the current value and a resistance value of the resistor.

12. The power source monitoring device according to claim 10, wherein:
the resistor includes a first resistor and a second resistor connected in series; and
the power source monitoring part detects a potential difference between a portion between the first resistor and the second resistor and a portion of the second resistor on a side not connected to the first resistor and calculates a value of a voltage applied to the resistor based on the potential difference and resistance values of the first resistor and the second resistor.

13. The power source monitoring device according to claim 10, wherein:
the resistor includes a first resistor, a second resistor, and a third resistor connected in series; and
the power source monitoring part detects a potential difference between a portion between the first resistor and the second resistor and a portion between the second resistor and the third resistor and calculates a value of a voltage applied to the resistor based on the potential difference and resistance values of the first to third resistors.

14. The power source monitoring device according to claim 10, wherein:
the second voltage applied part is a control circuit.

15. The power source monitoring device according to claim 10, wherein:
the first voltage applied part is a motor.

16. A lens barrel having a power source monitoring device according to claim 10.

17. A camera having a power source monitoring device according to claim 10.

18. A camera, comprising:
a camera body having a first voltage supply part that applies a first voltage to a first voltage applied part on the basis of a first portion and a second voltage supply part that applies a second voltage to a second voltage applied part on the basis of a second portion; and
a lens barrel having a resistor connected to the first portion and the first voltage applied part and applied with the first voltage and a power source monitoring part connected to the second portion and the second voltage applied part, operating when the second voltage is applied, and detecting a value of a voltage applied to the resistor.

19. A voltage monitoring method comprising the steps of:
providing a first voltage applied part applied with a first voltage by a first voltage supply part on the basis of a first portion;
providing a second voltage applied part applied with a second voltage by a second voltage supply part on the basis of a second portion; and
providing a voltage monitoring part connected to the second portion and the second voltage applied part, operating when the second voltage is applied, and detecting the first voltage on the basis of the first portion.

20. The power source monitoring method according to claim 19, further comprising the step of
providing a resistor connected to the first portion and the first voltage applied part and applied with the first voltage, wherein
the power source monitoring part detects the first voltage on the basis of the first portion by detecting a value of a voltage applied to the resistor.

21. The power source monitoring method according to claim 20, wherein:
the power source monitoring part detects a value of a current that flows through the resistor and calculates a value of a voltage applied to the resistor based on the current value and a resistance value of the resistor.

22. The power source monitoring method according to claim 20, wherein:
the resistor includes a first resistor and a second resistor connected in series; and
the power source monitoring part detects a potential difference between a portion between the first resistor and the second resistor and a portion of the second resistor on the side not connected to the first resistor and calculates a value of a voltage applied to the resistor based on the potential difference and resistance values of the first resistor and the second resistor.

23. The power source monitoring method according to claim 20, wherein:
the resistor includes a first resistor, a second resistor, and a third resistor connected in series; and
the power source monitoring part detects a potential difference between a portion between the first resistor and the second resistor and a portion between the second resistor and the third resistor and calculates a value of a voltage applied to the resistor based on the potential difference and resistance values of the first to third resistors.

24. The power source monitoring method according to claim 19, wherein:
the second voltage applied part is a control circuit.

25. The power source monitoring method according to claim 19, wherein:
the first voltage applied part is a motor.

26. A power source monitoring method comprising the steps of:
providing a first voltage applied part applied with a first voltage by a first voltage supply part on the basis of a first portion;
providing a second voltage applied part applied with a second voltage by a second voltage supply part on the basis of a second portion;
providing a resistor connected to the first portion and the first voltage applied part and applied with the first voltage; and
providing a power source monitoring part connected to the second portion and the second voltage applied part, operating when the second voltage is applied, and detecting a value of a voltage applied to the resistor.

27. The power source monitoring method according to claim 26, wherein:
the power source monitoring part detects a value of a current that flows through the resistor and calculates a value of a voltage applied to the resistor based on the current value and a resistance value of the resistor.

28. The power source monitoring method according to claim 26, wherein:
the resistor includes a first resistor and a second resistor connected in series; and
the power source monitoring part detects a potential difference between a portion between the first resistor and the second resistor and a portion of the second resistor on the side not connected to the first resistor and calculates a value of a voltage applied to the resistor based on the potential difference and resistance values of the first resistor and the second resistor.

29. The power source monitoring method according to claim 26, wherein:
the resistor includes a first resistor, a second resistor, and a third resistor connected in series; and
the power source monitoring part detects a potential difference between a portion between the first resistor and the second resistor and a portion between the second resistor and the third resistor and calculates a value of a voltage applied to the resistor based on the potential difference and resistance values of the first to third resistors.

30. The power source monitoring method according to claim 26, wherein:
the second voltage applied part is a control circuit.

31. The power source monitoring method according to claim 26, wherein:
the first voltage applied part is a motor.
